(19) United States
(12) Patent Application Publication
(10) Pub. No.: US 2023/0361754 A1
(43) Pub. Date: Nov. 9, 2023

(54) ACOUSTIC WAVE DEVICE, FILTER DEVICE, AND METHOD OF MANUFACTURING ACOUSTIC WAVE DEVICE

(71) Applicant: Murata Manufacturing Co., Ltd., Nagaokakyo, Kyoto (JP)

(72) Inventors: Yutaka KISHIMOTO, Nagaokakyo-shi (JP); Masashi OMURA, Nagaokakyo-shi (JP); Shintaro KUBO, Nagaokakyo-shi (JP); Hajime YAMADA, Nagaokakyo-shi (JP)

(73) Assignee: Murata Manufacturing Co., Ltd., Nagaokakyo, Kyoto (JP)

(21) Appl. No.: 18/341,775

(22) Filed: Jun. 27, 2023

Related U.S. Application Data
(63) Continuation of application No. PCT/JP2021/048094, filed on Dec. 24, 2021.

(30) Foreign Application Priority Data
Jan. 19, 2021 (JP) 2021-006431

(51) Int. Cl. H03H 9/17; H03H 9/56; H03H 3/02; H03H 9/02; H03H 9/13

(52) U.S. Cl. CPC H03H 9/173; H03H 9/568; H03H 3/02; H03H 9/02157; H03H 9/132; H03H 2003/021

(57) ABSTRACT

An acoustic wave device that includes a piezoelectric substrate that has a piezoelectric layer and a hollow portion, and first and second electrodes and. The piezoelectric layer has a first region that overlaps the first and second electrodes and the hollow portion in plan view, a second region that does not overlap the hollow portion and surrounds the first region in plan view, and a third region that overlaps the hollow portion and is located between the first region and the second region in plan view. A portion including the border between the first region and the third region of a cross-sectional shape in a lamination direction of the piezoelectric substrate includes a curved-surface shape.

### CROSS-REFERENCE TO RELATED APPLICATIONS

The present application is a bypass continuation of PCT/JP2021/048094, filed on Dec. 24, 2021, which claims priority to Japanese Patent Application 2021-006431, filed on Jan. 19, 2021, the entire contents of all of which are incorporated herein by reference.

### TECHNICAL FIELD

The present disclosure relates to an acoustic wave device, a filter device, and a method of manufacturing the acoustic wave device.

### BACKGROUND ART

Conventionally, an acoustic wave device is widely used in filters for mobile phones. Patent Document 1 below describes an example of a piezoelectric thin-film resonator as an acoustic wave device. This acoustic wave device includes a lower electrode on a substrate, a piezoelectric film on the lower electrode, and an upper electrode on the piezoelectric film. The region of the piezoelectric film sandwiched between the upper electrode and the lower electrode is a membrane region. A cavity is provided between the lower electrode and the substrate. A region on the surface of the substrate onto which the cavity has been projected includes the membrane region.

### CITATION LIST

### Patent Document

Patent Document 1: Japanese Patent No. 4707533

### SUMMARY OF DISCLOSURE

### Technical Problem

In the acoustic wave device described in Patent Document 1, application of an AC voltage across the upper electrode and the lower electrode excites an acoustic wave. However, in the acoustic wave device, it is difficult to sufficiently suppress an acoustic wave from leaking in a direction orthogonal to the lamination direction of the substrate and the piezoelectric film, that is, in the direction parallel to the surface of the substrate.

An object of the present disclosure is to provide an acoustic wave device, a filter device, and a method of manufacturing the acoustic wave device in which an acoustic wave is less likely to leak in a direction orthogonal to the lamination direction of a piezoelectric substrate.

### Solution to Problem

According to the present disclosure, there is provided a piezoelectric substrate including: a piezoelectric substrate that includes a support substrate and a piezoelectric layer provided on the support substrate, the piezoelectric substrate having a hollow portion; and an excitation electrode provided on the piezoelectric layer, in which the piezoelectric layer has a first region that overlaps the excitation electrode and the hollow portion in plan view, a second region that does not overlap the hollow portion and surrounds the first region in plan view, and a third region that overlaps the hollow portion and is located between the first region and the second region in plan view, a portion including a border between the first region and the third region of a cross-sectional shape in a lamination direction of the piezoelectric substrate includes a curved-surface shape, and t1M>t2 holds for a portion of the second region located at least at a border between the second region and the third region where a maximum thickness of the first region of the piezoelectric layer is t1M and a thickness of the second region of the piezoelectric layer is t2.

According to the present disclosure, there is provided a filter device including: a plurality of acoustic wave resonators including a first acoustic wave resonator and a second acoustic wave resonator, in which the first acoustic wave resonator is the acoustic wave device according to the present disclosure and the second acoustic wave resonator is the acoustic wave device according the present disclosure, the first acoustic wave resonator and the second acoustic wave resonator share the piezoelectric layer, and when a dimension of the hollow portion in the lamination direction of the piezoelectric substrate is a height of the hollow portion, a maximum height of the hollow portion of the first acoustic wave resonator is H1M, a maximum height of the hollow portion of the second acoustic wave resonator is H2M, a maximum thickness of a portion of the first region of the piezoelectric layer in which the first acoustic wave resonator is formed is T1M, and a maximum thickness of a portion of the first region of the piezoelectric layer in which the second acoustic wave resonator is formed is T2M, the maximum thickness T1M differs from the maximum thickness T2M, and the maximum height H1M differs from the maximum height H2M.

According to the present disclosure, there is provided a method of manufacturing the acoustic wave device according to the present disclosure, the method comprising: a hollow portion forming step of forming the hollow portion in the piezoelectric substrate; a thickness adjusting step of adjusting a thickness of the piezoelectric layer after the hollow portion forming step; and a step of providing the excitation electrode on the piezoelectric layer, in which an inner wall of the piezoelectric substrate that faces the hollow portion includes a bottom portion of portions that face each other in the lamination direction of the piezoelectric substrate, the bottom portion being close to the support substrate, thinning machining of the piezoelectric layer is performed in the thickness adjusting step, pressure toward the hollow portion is applied to the piezoelectric layer to place the piezoelectric layer into a deformed state in the thinning machining, a distance between a center of the bottom portion and the piezoelectric layer is smaller than a distance between an outer peripheral edge of the bottom portion of the inner wall of the piezoelectric substrate and the piezoelectric layer in the deformed state, and the piezoelectric layer is further deformed such that a distance between the piezoelectric layer and the bottom portion is greater than the distance in the deformed state by releasing the pressure applied to the piezoelectric layer after the piezoelectric layer is placed into the deformed state to meet t1M>t2.

### Advantageous Effects of Disclosure

In the acoustic wave device, the filter device, and the method of manufacturing the acoustic wave device according to the present disclosure, an acoustic wave is less likely to leak in a direction orthogonal to the lamination direction of the piezoelectric substrate.

### BRIEF DESCRIPTION OF DRAWINGS

FIG. 1 is a schematic elevational cross-sectional view of an acoustic wave device according to a first embodiment of the present disclosure.

FIG. 2 is a schematic elevational cross-sectional view of an acoustic wave device according to a modification of the first embodiment of the present disclosure.

FIGS. 3A and 3B are schematic elevational cross-sectional views for describing a step of preparing a piezoelectric layer and the like in an example of a method of manufacturing the acoustic wave device according to the first embodiment of the present disclosure.

FIGS. 4A and 4B are schematic elevational cross-sectional views for describing a step of preparing a support substrate and the like in an example of a method of manufacturing the acoustic wave device according to the first embodiment of the present disclosure.

FIGS. 5A to 5E are schematic elevational cross-sectional views for describing a step of joining the piezoelectric layer and the support substrate to each other and subsequent steps in an example of the method of manufacturing the acoustic wave device according to the first embodiment of the present disclosure.

FIGS. 6A to 6C are schematic elevational cross-sectional views for describing a step of preparing the piezoelectric layer and the like in an example of a method of manufacturing an acoustic wave device according to a modification of the first embodiment of the present disclosure.

FIGS. 7A to 7C are schematic elevational cross-sectional views for describing the step of preparing the support substrate and subsequent steps in the example of the method of the manufacturing the acoustic wave device according to the modification of the first embodiment of the present disclosure.

FIG. 8 is a schematic elevational cross-sectional view of an acoustic wave device according to a second embodiment of the present disclosure.

FIG. 9 is a plan view illustrating the electrode structure of an IDT electrode and a reflector according to the second embodiment of the present disclosure.

FIG. 10 is a schematic elevational cross-sectional view of a filter device according to a third embodiment of the present disclosure.

FIG. 11 is a circuit diagram of a filter device according to a fourth embodiment of the present disclosure.

### DESCRIPTION OF EMBODIMENTS

The present disclosure will be clarified below by describing specific embodiments of the present disclosure with reference to the drawings.

It should be noted that the embodiments described in this specification are exemplary and that partial replacement or combinations of the structures of different embodiments are possible.

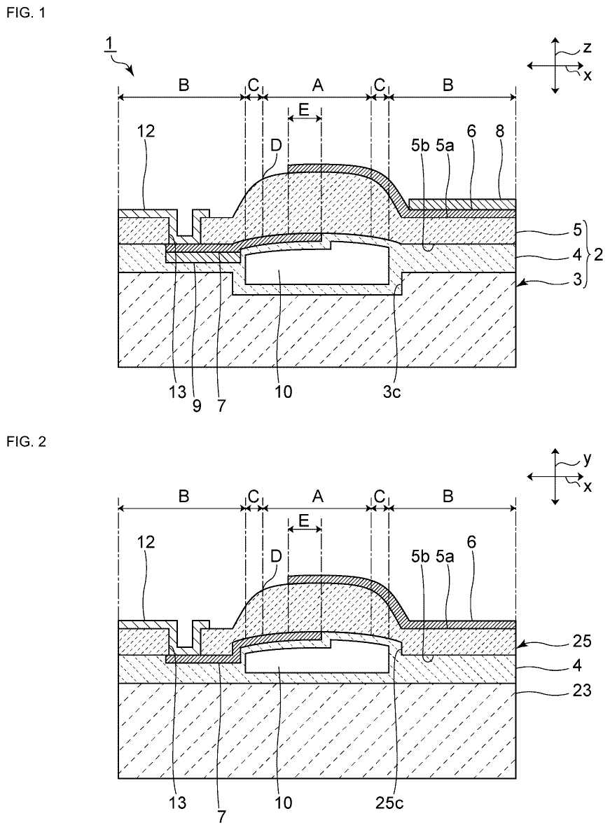

FIG. 1 is a schematic elevational cross-sectional view of an acoustic wave device according to a first embodiment of the present disclosure.

An acoustic wave device 1 includes a piezoelectric substrate 2. In the present embodiment, the piezoelectric substrate 2 includes a support substrate 3, an intermediate layer 4, and a piezoelectric layer 5. More specifically, the intermediate layer 4 is provided between the support substrate 3 and the piezoelectric layer 5. However, the piezoelectric substrate 2 need not include the intermediate layer 4.

The material of the support substrate 3 may be a piezoelectric substance, such as lithium tantalate, lithium niobate, or quartz, various ceramics, such as alumina, sapphire, magnesia, silicon nitride, aluminum nitride, silicon carbide, zirconia, cordierite, mullite, steatite, or forsterite, a dielectric, such as diamond or glass, a semiconductor, such as silicon or gallium nitride, or a resin. It should be noted that the material of the support substrate 3 is preferably silicon, sapphire, glass, or quartz.

The material of the intermediate layer 4 may be, for example, silicon oxide, silicon nitride, silicon oxynitride, or the like. It should be noted that the material of the intermediate layer 4 is preferably silicon oxide.

The piezoelectric layer 5 has a first main surface 5a and a second main surface 5b. The first main surface 5a and the second main surface 5b face away from each other. Of the first main surface 5a and the second main surface 5b, the second main surface 5b is the main surface closer to the support substrate 3. The material of the piezoelectric layer 5 may be, for example, lithium tantalate, lithium niobate, zinc oxide, aluminum nitride, quartz, or PZT. It should be noted that the material of the piezoelectric layer 5 is preferably lithium tantalate, lithium niobate, or a single crystal material of quartz. The thickness of the piezoelectric layer 5 is preferably 1 μm or less.

Excitation electrodes are provided on the piezoelectric layer 5. More specifically, according to the present embodiment, the pair of excitation electrodes is formed of a first electrode 6 and a second electrode 7. The first electrode 6 is provided on the first main surface 5a of the piezoelectric layer 5. The second electrode 7 is provided on the second main surface 5b. The first electrode 6 and the second electrode 7 face each other across the piezoelectric layer 5. The region of the piezoelectric layer 5 sandwiched between the first electrode 6 and the second electrode 7 is an excitation region E. Application of an AC voltage across the first electrode 6 and the second electrode 7 excites an acoustic wave in the excitation region E. Specifically, a bulk wave is excited in the present embodiment. As described above, the acoustic wave device 1 is a bulk wave resonator.

Each of the excitation electrodes is made of at least one metal selected from the group including, for example, Al, Pt, Cu, W, and Mo. However, the excitation electrode need only be made of an appropriate metal. The excitation electrode may be made of a single-layer metal film or a laminated metal film.

As illustrated in FIG. 1, a hollow portion 10 is provided in the piezoelectric substrate 2. The hollow portion 10 is enclosed by the intermediate layer 4. In the present embodiment, the hollow portion 10 is provided to span the intermediate layer 4 and the support substrate 3. More specifically, a recessed portion 3c is provided in the support substrate 3. The intermediate layer 4 is also provided in the recessed portion 3c of the support substrate 3, and the hollow portion 10 leads to the recessed portion 3c. Providing the hollow portion 10 enables a bulk wave to be efficiently excited.

The piezoelectric layer 5 includes a first region A, a second region B, and a third region C. The first region A overlaps the first electrode 6 and the second electrode 7, which are the excitation electrodes, and the hollow portion 10 in plan view. More specifically, the first region A overlaps a part of the first electrode 6, a part of the second electrode 7, and a part of the hollow portion 10 in plan view. The first region A includes the excitation region E. The second region B does not overlap the hollow portion 10 and surrounds the first region A in plan view. The third region C overlaps the hollow portion 10 and is located between the first region A and the second region B in plan view. It should be noted that “plan view” in this specification indicates a view seen from above in FIG. 1

As illustrated in FIG. 1, a piezoelectric layer 5 portion that overlaps the hollow portion 10 in plan view has a convex shape that projects away from the support substrate 3. The first region A and the third region C are located in this convex portion. On the other hand, the second region B is a region including a flat portion of the piezoelectric layer 5.

The excitation region E is also included in the convex portion of the piezoelectric layer 5. Accordingly, the first electrode 6 and the second electrode 7 have portions curved along the piezoelectric layer 5. An electrode layer 8 is provided on a flat portion of the first electrode 6. An electrode layer 9 is provided on a flat portion of the second electrode 7. This can reduce electric resistance. However, the electrode layer 8 and the electrode layer 9 may extend to portions that are not flat.

A through-hole 13 is provided in the piezoelectric layer 5. The through-hole 13 leads to the second electrode 7. On the other hand, in the second region B of the piezoelectric layer 5, a wiring electrode 12 is provided on the first main surface 5a. The wiring electrode 12 passes through the through-hole 13 and is connected to the second electrode 7. The second electrode 7 is electrically connected to the outside via the wiring electrode 12.

Here, it is assumed that the lamination direction of the piezoelectric substrate 2 is a first direction z and that the direction orthogonal to the first direction z is a second direction x. The present embodiment is characterized by meeting the conditions described in (1) and (2) below. (1) The cross-sectional shape of the piezoelectric layer 5 in the first direction z includes a curved-surface shape in a portion including a border D between the first region A and the third region C. (2) When it is assumed that the maximum thickness of the piezoelectric layer 5 in the first region A is t1M and that the thickness in the second region B is t2, t1M>t2 holds. As described above, the first region A includes the excitation region E. The thickness t2 in the surrounding second region B is smaller than the thickness t1M in this first region A. This can suppress a bulk wave as an acoustic wave from leaking in the second direction x of the piezoelectric substrate 2. Furthermore, since a piezoelectric layer 5 portion including the border D between the first region A and the third region C includes a curved-surface shape, concentration of stress can be dispersed and the piezoelectric layer 5 can be suppressed from being damaged.

The thickness t2 of a portion located at least at the border between the second region B and the third region C in the second region B need only be smaller than the thickness t1M in the first region A. This can suppress an acoustic wave from leaking in the second direction x.

Here, it is assumed that the thickness in the first region A is t1 and that the thickness in the third region C is t3. In the present embodiment, t1>t3>t2 holds. When the portions to which the thicknesses t1, t2, and t3 pertain are not described, the thicknesses t1, t2, and t3 indicate arbitrary portions in the first region A, the second region B, and the third region C. Accordingly, when, for example, t1>t3 holds, the thickness of any portion of the first region A is greater than the thickness of any portion of the third region C. It should be noted that, when comparing the thicknesses of adjacent regions, the thickness of the border portion between adjacent regions is not included. The third region C is adjacent to the first region A, and the thickness t3 in the third region C is smaller than the thickness t1 in the first region A. This can effectively suppress an acoustic wave from leaking in the second direction x. However, t1M>t2 need only hold regardless of the relationship of the thicknesses described above.

As illustrated in FIG. 1, the piezoelectric layer 5 portion that overlaps the hollow portion 10 in plan view preferably has a convex shape that projects away from the support substrate 3. In this case, the relationship t1>t3>t2 can be ensured with greater certainty.

In the present embodiment, the thickness of the piezoelectric layer 5 decreases toward the outside in the second direction x from the center of the first region A. Here, when it is assumed that the distance in the second direction x between two points on the piezoelectric layer 5 is Lx and that the difference in the thickness of the piezoelectric layer 5 at the two points is Δt, the gradient of change in the thickness of the piezoelectric layer 5 is Δt/Lx. The gradient Δt/Lx of change in the thickness in the third region C is greater than the gradient Δt/Lx of change in the thickness in the first region A. As illustrated in FIG. 1, the gradient Δt/Lx of change in the thickness of the piezoelectric layer 5 changes greatly at the border D between the first region A and the third region C. It should be noted that the curvature at the border D between the first region A and the third region C is greater than the curvature of any other portion in the first region A and the curvature of any other portion in the third region C in the cross-sectional shape in the first direction z of the first main surface 5a of the piezoelectric layer 5. Accordingly, as described above, the gradient Δt/Lx of change in the thickness of the piezoelectric layer 5 changes greatly at the border D. In this case, since the change in the thickness of the piezoelectric layer 5 can be steep outside the first region A including the excitation region E, an acoustic wave can be further suppressed from leaking.

The distance between the excitation region E and the border D between the first region A and the third region C is preferably 0 μm or more and 2 μm or less. In this case, the excitation region E can be suitably widened, and the excitation efficiency can be improved.

The electrode layer 8 and the electrode layer 9 are preferably provided on flat portions of the first electrode 6 and the second electrode 7, respectively. In this case, the total thickness of the electrodes in a piezoelectric layer 5 portion to be formed in a convex shape in manufacturing is small. Accordingly, the piezoelectric layer 5 is easily formed in a convex shape. It should be noted that the electrode layer 8 and the electrode layer 9 may also be provided in the curved portions of the first electrode 6 and the second electrode 7, respectively. Alternatively, the electrode layer 8 and the electrode layer 9 need not be provided.

In the present embodiment, the hollow portion 10 is provided to span the intermediate layer 4 and the support substrate 3. The thickness of the support substrate 3 is greater than the thicknesses of the piezoelectric layer 5 and the intermediate layer 4. Accordingly, the depth of the recessed portion 3c can be easily increased. Accordingly, the height of the hollow portion 10 can be easily increased. As a result, the hollow portion 10 is less likely to collapse due to an external force, thermal stress, or the like, and the walls within the hollow portion 10 are less likely to come into contact with each other. It should be noted that, in this specification, the height of the hollow portion 10 is the dimension in the first direction z of the hollow portion 10. The height of the hollow portion 10 can be adjusted by changing the depth of the recessed portion 3c of the support substrate 3. Accordingly, the height of the hollow portion 10 can be easily adjusted without affecting the thicknesses of the piezoelectric layer 5 and the intermediate layer 4.

It should be noted that the position of the hollow portion 10 in the piezoelectric substrate 2 is not limited to that described above. At least a part of the hollow portion 10 may be provided in the intermediate layer 4. At least a part of the hollow portion 10 may be provided in the support substrate 3. Alternatively, at least a part of the hollow portion 10 may be provided in the piezoelectric layer 5. The hollow portion 10 may be disposed in only the support substrate 3, in only the intermediate layer 4, or in only the piezoelectric layer 5.

FIG. 2 is a schematic elevational cross-sectional view of the acoustic wave device according to the modification of the first embodiment.

In the present embodiment, the hollow portion 10 is provided to span a piezoelectric layer 25 and the intermediate layer 4. More specifically, the second main surface 5b of the piezoelectric layer 25 has a recessed portion 25c. The recessed portion 25c provided in the piezoelectric layer 25 forms a step portion. The intermediate layer 4 is also provided in the recessed portion 25c of the piezoelectric layer 25, and the hollow portion 10 leads to the recessed portion 25c. This can easily increase the height of the hollow portion 10. As a result, the hollow portion 10 is less likely to collapse due to an external force, thermal stress, or the like, and the walls within the hollow portion 10 are less likely to come into contact with each other. Since t1>t3>t2 holds in the present modification as in the first embodiment, an acoustic wave can be effectively suppressed from leaking in the second direction x.

In the present modification, the electrode layer 8 and the electrode layer 9 are not laminated on the first electrode 6 and the second electrode 7, respectively. However, the electrode layer 8 and the electrode layer 9 may be provided as in the first embodiment.

As in the present embodiment or the modification thereof, the hollow portion 10 is preferably provided to span the intermediate layer 4 and the support substrate 3 or the intermediate layer 4 and the piezoelectric layer 5. This can easily increase the height of the hollow portion 10 as described above.

It should be noted that a slit may be provided in a part of the periphery of the first region A in the piezoelectric layer 5. For example, when the first region A has a rectangular shape in plan view, at least one of the four sides around the first region A may have a slit. In this case as well, the second region B surrounds the first region A. In addition, as in the first embodiment, an acoustic wave can be effectively suppressed from leaking in the second direction x.

A method of manufacturing the acoustic wave devices according to the first embodiment and the modification thereof will be described below. However, the method of manufacturing the acoustic wave device according to the present disclosure is not limited to the following method.

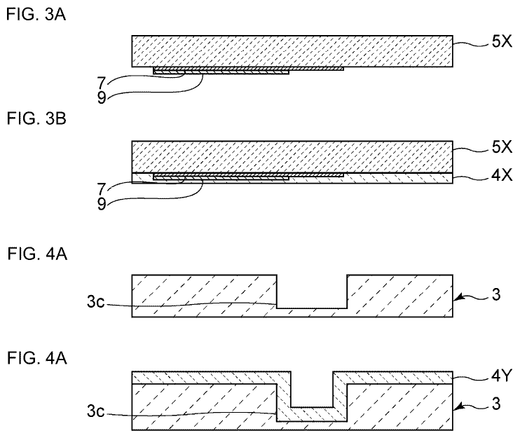

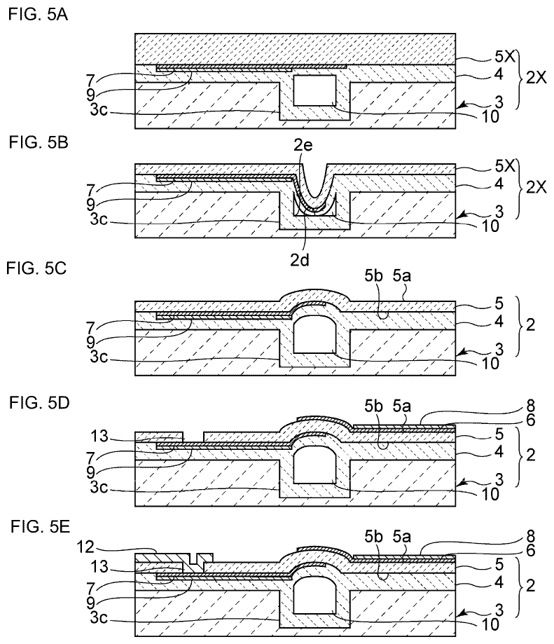

FIGS. 3A and 3B are schematic elevational cross-sectional views for describing a step of preparing the piezoelectric layer and the like in an example of the method of manufacturing the acoustic wave device according to the first embodiment. FIGS. 4A and 4B are schematic elevational cross-sectional views for describing a step of preparing the support substrate and the like in an example of the method of manufacturing the acoustic wave device according to the first embodiment. FIGS. 5A to 5E are schematic elevational cross-sectional views for describing a step of joining the piezoelectric layer and the support substrate to each other and subsequent steps in an example of the method of manufacturing the acoustic wave device according to the first embodiment.

As illustrated in FIG. 3A, a piezoelectric layer 5X is prepared. The piezoelectric layer 5X is a piezoelectric substrate. Next, the second electrode 7 is provided on one main surface of the piezoelectric layer 5X. Next, the electrode layer 9 is provided on the second electrode 7. The second electrode 7 and the electrode layer 9 can be formed by, for example, a vapor deposition lift-off method that uses a photolithography method.

Next, as illustrated in FIG. 3B, an intermediate layer 4X is formed on one main surface of the piezoelectric layer 5X so as to cover the second electrode 7. The intermediate layer 4X can be formed by, for example, a sputtering method or a vacuum deposition method.

On the other hand, as illustrated in FIG. 4A, the recessed portion 3c is provided in one main surface of the support substrate 3. The recessed portion 3c can be formed by, for example, an RIE (reactive ion etching) method.

Next, as illustrated in FIG. 4B, an intermediate layer 4Y is formed on one main surface of the support substrate 3 so as to lead to the inside of the recessed portion 3c. The intermediate layer 4Y can be formed by, for example, a sputtering method or a vacuum deposition method.

Next, as illustrated in FIG. 5A, a piezoelectric substrate 2X is obtained by joining the piezoelectric layer 5X and the support substrate 3 to each other. More specifically, in the present embodiment, the intermediate layer 4X on the piezoelectric layer 5X and the intermediate layer 4Y on the support substrate 3 are joined to each other. This forms the intermediate layer 4 and the hollow portion 10. The intermediate layer 4X and the intermediate layer 4Y can be joined to each other by a direct joint, a plasma activated joint, an atomic diffusion joint, or the like.

The inner wall of the piezoelectric substrate 2X that faces the hollow portion 10 includes an upper surface portion and a bottom portion. The upper surface portion and the bottom portion face each other in the first direction z. The upper surface portion is located on the piezoelectric layer 5X side. The bottom portion is located on the support substrate 3 side.

After the hollow portion forming step, the thickness of the piezoelectric layer 5X is adjusted as illustrated in FIG. 5B. More specifically, in this thickness adjusting step, thinning machining is performed on the piezoelectric layer 5X. The thinning of the piezoelectric layer 5X can be performed by grinding and polishing the piezoelectric layer 5X by using, for example, a grinding or CMP (chemical mechanical polishing) method. At this time, in grinding and polishing of the piezoelectric layer 5X, pressure is applied to the piezoelectric layer 5X toward the hollow portion 10 to place the piezoelectric layer 5X into the deformed state. In the deformed state of the piezoelectric layer 5X, the thickness of the piezoelectric layer 5X is sufficiently small. Accordingly, in the deformed state, in a part of the piezoelectric layer 5X, one main surface and the other main surface both have convex shapes that project to the hollow portion 10. It should be noted that, when pressure is applied to the piezoelectric layer 5X toward the hollow portion 10, the pressure is also applied to the intermediate layer 4 via the piezoelectric layer 5X. Accordingly, in the deformed state, a part of the intermediate layer 4 also has a convex shape.

In the deformed state described above, the distance between a center 2d of the bottom portion of the inner wall of the piezoelectric substrate 2X and the piezoelectric layer 5X is made smaller than the distance between an outer peripheral edge 2e of the bottom portion and the piezoelectric layer 5X. These distances are adjusted by controlling the machining pressure applied to the piezoelectric layer 5X or the inner pressure of the hollow portion 10. The inner pressure of the hollow portion 10 can be controlled by adjusting the atmospheric pressure applied to join the piezoelectric layer 5X and the support substrate 3 to each other. In the case illustrated in FIG. 5B, a part of the upper surface portion and the bottom portion of the inner wall of the piezoelectric substrate 2X are in contact with each other. However, the upper surface portion and the bottom portion need not necessarily be in contact with each other.

Next, by releasing the pressure applied to the piezoelectric layer 5X, the piezoelectric layer 5 is further deformed to make the distance between the piezoelectric layer 5 and the bottom portion longer than the distance in the deformed state, as illustrated in FIG. 5C. This can form the first region A, the second region B, and the third region C of the piezoelectric layer 5 illustrated in FIG. 1. As a result, t1M>t2 holds.

Next, as illustrated in FIG. 5D, the first electrode 6 is formed on the first main surface 5a of the piezoelectric layer 5. Next, the electrode layer 8 is provided on the first electrode 6. The first electrode 6 and the electrode layer 8 can be formed by, for example, a vapor deposition lift-off method that uses a photolithography method.

Next, a through-hole 13 is formed in the piezoelectric layer 5 so as to lead to the second electrode 7. The through-hole 13 can be formed by, for example, an RIE method. Next, as illustrated in FIG. 5E, the wiring electrode 12 is formed. The wiring electrode 12 can be formed by, for example, a vapor deposition lift-off method that uses a photolithography method. As described above, the acoustic wave device 1 is obtained.

In the step illustrated in FIG. 5B, the upper surface portion and the bottom portion of the inner wall of the piezoelectric substrate 2X are preferably in contact with each other. This can form a flat portion in the first region A with greater certainty. In this case, the electrical characteristics of the acoustic wave device 1 can be easily stabilized. Here, a portion of the upper surface portion in contact with the bottom portion is assumed to be a contact portion. The vicinity of a piezoelectric layer 5X portion that overlaps the outer peripheral edge of the contact portion in plan view is the border D between the first region A and the third region C illustrated in FIG. 1. As described above, the curvature at the border D can be easily increased, and an acoustic wave can be easily and effectively suppressed from leaking in the second direction x.

The depth of the recessed portion 3c of the support substrate 3 is preferably several hundred nanometers or less. This can easily bring the upper surface portion of the inner wall of the piezoelectric substrate 2X into contact with the bottom portion of the inner wall in the step illustrated in FIG. 5B. Accordingly, a flat portion can be formed with much greater certainty in the first region A.

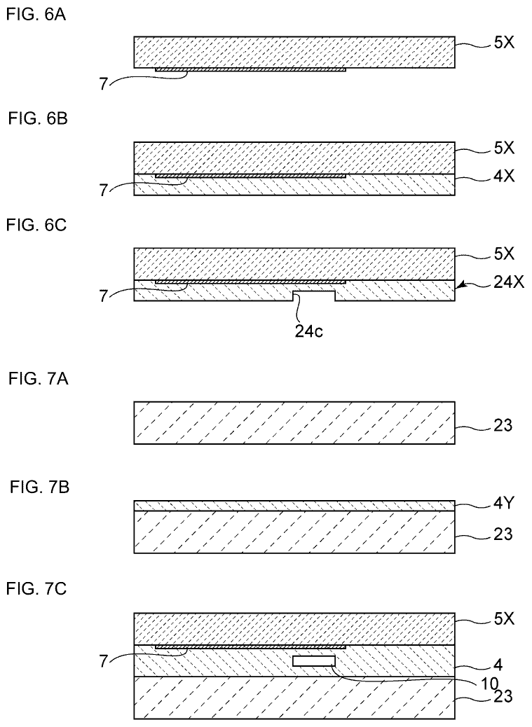

FIGS. 6A to 6C are schematic elevational cross-sectional views for describing a step of preparing the piezoelectric layer and the like in an example of a method of manufacturing the acoustic wave device according to the modification of the first embodiment. FIGS. 7A to 7C are schematic elevational cross-sectional views for describing a step of preparing the support substrate and subsequent steps in an example of the method of manufacturing the acoustic wave device according to the modification of the first embodiment.

As illustrated in FIG. 6A, the piezoelectric layer 5X is prepared. Next, the second electrode 7 is provided on one main surface of the piezoelectric layer 5X. Next, as illustrated in FIG. 6B, the intermediate layer 4X is formed on one main surface of the piezoelectric layer 5X to cover the second electrode 7. The second electrode 7 and the intermediate layer 4X can be formed in the same way as in the first embodiment.

Next, a recessed portion is provided in one main surface of the intermediate layer 4X. As a result, an intermediate layer 24X is obtained as illustrated in FIG. 6C. A recessed portion 24c of the intermediate layer 24X is provided to overlap the second electrode 7 in plan view. The recessed portion 24c can be provided by, for example, an RIE method. The depth of the recessed portion 24c is preferably several hundred nanometers or less.

On the other hand, a support substrate 23 is prepared as illustrated in FIG. 7A. Next, as illustrated in FIG. 7B, an intermediate layer 4Y is formed in one main surface of the support substrate 23. The intermediate layer 4Y can be formed by, for example, a sputtering method or a vacuum deposition method.

Next, as illustrated in FIG. 7C, the piezoelectric layer 5X and the support substrate 23 are joined to each other. More specifically, when the acoustic wave device according to the present modification is manufactured, the intermediate layer 24X on the piezoelectric layer 5X and the intermediate layer 4Y on the support substrate 3 are joined to each other. This forms the intermediate layer 4 and the hollow portion 10. The intermediate layer 24X and the intermediate layer 4Y can be joined to each other by a direct joint, a plasma activated joint, an atomic diffusion joint, or the like. Subsequent steps may be performed in the same way as in the method of manufacturing the acoustic wave device 1 according to the first embodiment described above. This can obtain the acoustic wave device according to the present modification.

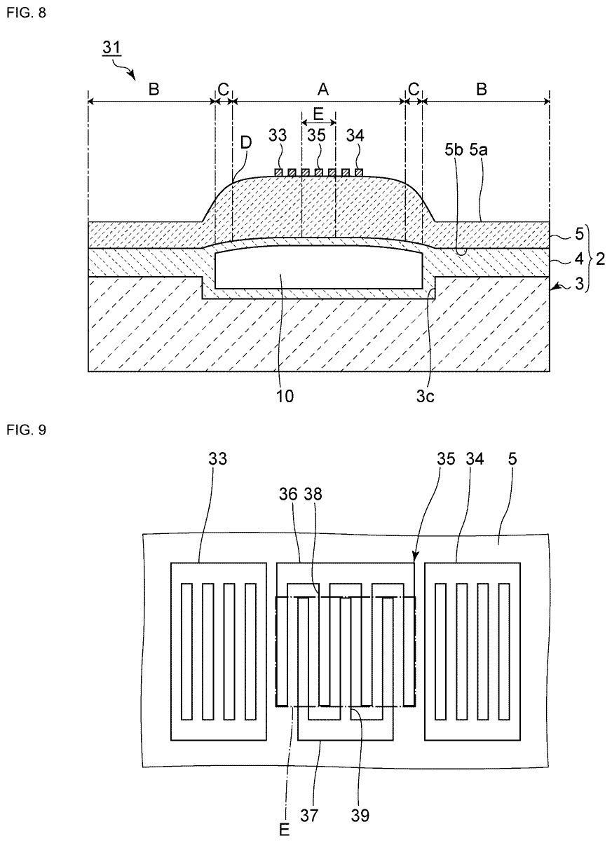

FIG. 8 is a schematic elevational cross-sectional view of an acoustic wave device according to a second embodiment.

The present embodiment differs from the first embodiment in that the excitation electrode is an IDT electrode 35 and that a pair of reflectors 33 and 34 is provided. The acoustic wave device 31 according to the present embodiment has the same structure as the acoustic wave device 1 according to the first embodiment with the exception of the points described above.

The IDT electrode 35 is provided on the first main surface 5a of the piezoelectric layer 5. The reflector 33 and the reflector 34 are provided on respective sides in the acoustic wave propagation direction of the IDT electrode 35 on the first main surface 5a. In the present embodiment, the acoustic wave device 31 is a surface acoustic wave resonator.

The IDT electrode 35, the reflector 33, and the reflector 34 are preferably provided on a flat portion of the first main surface 5a in the first region A. This can easily stabilize the electrical characteristics of the acoustic wave device 31. Here, in the first region A, the first main surface 5a of the piezoelectric layer 5 is further inclined in the first direction z toward the third region C. In the present embodiment, the IDT electrode 35 is provided in a portion including the center of the first region A in the acoustic wave propagation direction. This enables the IDT electrode 35 to be positioned in a flat portion of the piezoelectric layer 5 with greater certainty.

FIG. 9 is a plan view illustrating the electrode structure of an IDT electrode and reflectors according to the second embodiment.

The IDT electrode 35 includes a first busbar 36, a second busbar 37, a plurality of first electrode fingers 38, and a plurality of second electrode fingers 39. The first busbar 36 and the second busbar 37 face each other. Ends of the plurality of first electrode fingers 38 are connected to the first busbars 36. Ends of the plurality of second electrode fingers 39 are connected to the second busbars 37. The plurality of first electrode fingers 38 and the plurality of second electrode fingers 39 are interdigitated with each other. In the present embodiment, the adjacent first and second electrode fingers 38 and 39 overlap each other in the excitation region E as viewed in the acoustic wave propagation direction.

In the present embodiment as well, t1M>t2 holds. This can suppress an acoustic wave from leaking in the second direction x.

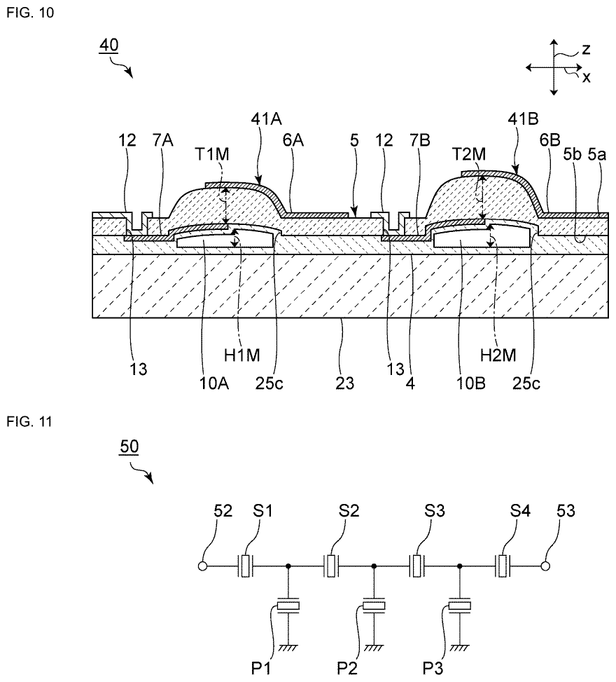

FIG. 10 is a schematic elevational cross-sectional view of a filter device according to a third embodiment.

The filter device 40 includes a plurality of acoustic wave resonators. More specifically, the plurality of acoustic wave resonators are a first acoustic wave resonator 41A and a second acoustic wave resonator 41B. The first acoustic wave resonator 41A and the second acoustic wave resonator 41B both have the same structure as in the modification of the first embodiment. However, the plurality of acoustic wave resonators of the filter device 40 need only have the structure of the acoustic wave device according to the present disclosure. The number of acoustic wave resonators in the filter device 40 is not particularly limited.

Here, in the present embodiment, the filter device 40 has a plurality of excitation electrodes and a plurality of hollow portions that correspond to the plurality of acoustic wave resonators, respectively. The excitation electrodes of the first acoustic wave resonator 41A are a first electrode 6A and a second electrode 7A pair. The hollow portion of the first acoustic wave resonator 41A is a hollow portion 10A. The excitation electrodes of the second acoustic wave resonator 41B are a first electrode 6B and a second electrode 7B pair. The hollow portion of the second acoustic wave resonator 41B is a hollow portion 10B.

The first acoustic wave resonator 41A and the second acoustic wave resonator 41B share the piezoelectric layer 5. Accordingly, the piezoelectric layer 5 has the first region A, the second region B, and the third region C in each of the portions in which the first acoustic wave resonator 41A is formed and in which the second acoustic wave resonator 41B is formed.

As described above, the filter device 40 includes the acoustic wave resonator having the structure according to the modification of the first embodiment. Accordingly, an acoustic wave can be suppressed from leaking in the second direction x in the same way as in the modification.

Here, in the present embodiment, when it is assumed that the maximum height of the hollow portion 10A is H1M and that the maximum height of the hollow portion 10B is H2M, H2M>H1M holds. In the piezoelectric layer 5, when it is assumed that the maximum thickness in the first region A of the portion in which the first acoustic wave resonator 41A is formed is T1M and that the maximum thickness in the first region A of the portion in which the second acoustic wave resonator 41B is formed is T2M, T2M>T1M holds. However, the present disclosure is not limited to the example described above, and it is sufficient that H1M and H2M differ from each other and that T1M and T2M differ from each other.

As in the present embodiment, when both T2M>T1M and H2M>H1M hold, excitation efficiency can be increased with greater certainty. More specifically, in excitation of an acoustic wave, the greater the thickness of the piezoelectric layer 5, the greater the displacement of the piezoelectric layer 5. On the other hand, the greater the height of the hollow portion, the less likely the upper surface portion and the bottom portion of the inner wall come into contact with each other, and the less likely the excitation is inhibited. Accordingly, by meeting both T2M>T1M and H2M>H1M, inhibition of excitation can be suppressed with greater certainty, and excitation efficiency can be increased with greater certainty.

On the other hand, T2M>T1M and H1M>H2M may hold. In this case, inner walls of the hollow portion can be suppressed from being in contact with each other. More specifically, the greater the thickness of the piezoelectric layer 5, the greater the deformation of the piezoelectric layer 5 when the temperature changes. On the other hand, the greater the height of the hollow portion, the less likely the upper surface portion and the bottom portion of the inner wall come into contact with each other. Accordingly, when both T2M>T1M and H1M>H2M hold, inner walls of the hollow portion can be suppressed from being in contact with each other when temperature changes.

FIG. 11 is a circuit diagram of a filter device according to a fourth embodiment.

A filter device 50 according to the present embodiment is a ladder filter. The filter device 50 includes a first signal end S2, a second signal end 53, a plurality of series arm resonators, and a plurality of parallel arm resonators. More specifically, the plurality of series arm resonators of the filter device 50 are a series arm resonator S1, a series arm resonator S2, a series arm resonator S3, and a series arm resonator S4. The plurality of parallel arm resonators are a parallel arm resonator P1, a parallel arm resonator P2, and a parallel arm resonator P3. The first signal end 52 is an antenna end. That is, the first signal end 52 is connected to an antenna. The first signal end 52 and the second signal end 53 may be configured as electrode pads or may be configured as wiring.

The series arm resonator S1, the series arm resonator S2, the series arm resonator S3, and the series arm resonator S4 are connected in series with each other between the first signal end 52 and the second signal end 53. The parallel arm resonator P1 is connected between the ground potential and the connection point between the series arm resonator S1 and the series arm resonator S2. The parallel arm resonator P2 is connected between the ground potential and the connection point between the series arm resonator S2 and the series arm resonator S3. The parallel arm resonator P3 is connected between the ground potential and the connection point between the series arm resonator S3 and the series arm resonator S4.

It should be noted that the circuit structure of the filter device 50 is not limited to the circuit structure described above. The filter device 50 need only have at least one series arm resonator and at least one parallel arm resonator. In the present embodiment, each of the series arm resonators and each of the parallel arm resonators of the filter device 50 are the acoustic wave device according to the present disclosure. Accordingly, an acoustic wave can be suppressed from leaking in the second direction x. However, at least one series arm resonator of the filter device 50 need only be the acoustic wave device according to the present disclosure and at least one parallel arm resonator of the filter device 50 need only be the acoustic wave device according to the present disclosure.

In the present embodiment, the series arm resonator S1 is the first acoustic wave resonator 41A according to the third embodiment. On the other hand, the parallel arm resonator P1 is the second acoustic wave resonator 41B according to the third embodiment. As described above, T2M>T1M holds. Accordingly, in the piezoelectric layer 5, the maximum thickness of the first region A including the excitation region E of the series arm resonator S1 is smaller than the maximum thickness of the first region A including the excitation region E of the parallel arm resonator P1. This can easily increase the resonant frequency of the series arm resonator S1. Similarly, the resonant frequency of the parallel arm resonator P1 can be easily decreased.

### REFERENCE SIGNS LIST

1 acoustic wave device
2, 2X piezoelectric substrate
2d center
2e outer peripheral edge
3 support substrate
3c recessed portion
4, 4X, 4Y intermediate layer
5, 5X piezoelectric layer
5a, 5b first and second main surfaces
6, 6A, 6B first electrode
7, 7A, 7B second electrode
8, 9 electrode layer
10, 10A, 10B hollow portion
12 wiring electrode
13 through-hole
23 support substrate
24X intermediate layer
24c recessed portion
25 piezoelectric layer
25c recessed portion
31 acoustic wave device
33, 34 reflector
35 IDT electrode
36, 37 first and second busbars
38, 39 first and second electrode fingers
40 filter device
41A, 41B first and second acoustic wave resonators
50 filter device
52, 53 first and second signal ends
A to C first to third regions
D border
E excitation region
P1 to P3 parallel arm resonator
S1 to S4 series arm resonator

1. An acoustic wave device comprising:
a piezoelectric substrate that includes a support substrate and a piezoelectric layer provided on the support substrate, the piezoelectric substrate having a hollow portion; and
an excitation electrode provided on the piezoelectric layer,
wherein the piezoelectric layer has a first region that overlaps the excitation electrode and the hollow portion in plan view, a second region that does not overlap the hollow portion and surrounds the first region in plan view, and a third region that overlaps the hollow portion and is located between the first region and the second region in plan view,
a portion including a border between the first region and the third region of a cross-sectional shape in a lamination direction of the piezoelectric substrate includes a curved-surface shape, and
t1M>t2 holds for a portion of the second region located at least at a border between the second region and the third region where a maximum thickness of the first region of the piezoelectric layer is t1M and a thickness of the second region of the piezoelectric layer is t2.

2. The acoustic wave device according to claim 1,
wherein t1>t3>t2 holds where a thickness of the first region of the piezoelectric layer is t1 and a thickness of the third region is t3.

3. The acoustic wave device according to claim 1,
wherein a portion of the piezoelectric layer that overlaps the hollow portion in plan view has a convex portion that projects away from the support substrate.

4. The acoustic wave device according to claim 1,
wherein the piezoelectric layer has a first main surface and a second main surface that face away from each other, and of the first main surface and the second main surface, the second main surface is closer to the support substrate, and a curvature at a border between the first region and the third region is greater than curvature of any other portion in the first region and curvature of any other portion in the third region in a cross-sectional shape in the lamination direction of the first main surface of the piezoelectric layer.

5. The acoustic wave device according to claim 1,
wherein at least a part of the hollow portion is provided in the piezoelectric layer.

6. The acoustic wave device according to claim 1,
wherein the piezoelectric substrate includes an intermediate layer provided between the support substrate and the piezoelectric layer, and at least a part of the hollow portion is provided in the intermediate layer.

7. The acoustic wave device according to claim 1,
wherein at least a part of the hollow portion is provided in the support substrate.

8. The acoustic wave device according to claim 1,
wherein the excitation electrode is an IDT electrode.

9. The acoustic wave device according to claim 1,
wherein the piezoelectric layer has the first main surface and the second main surface that face away from each other, the excitation electrode includes a first electrode and a second electrode pair, the first electrode is provided on the first main surface of the piezoelectric layer, the second electrode is provided on the second main surface of the piezoelectric layer, the first electrode and the second electrode face each other across the piezoelectric layer, and a region of the piezoelectric layer sandwiched between the first electrode and the second electrode is included in the first region.

10. A filter device comprising:
a plurality of acoustic wave resonators including a first acoustic wave resonator and a second acoustic wave resonator,
wherein the first acoustic wave resonator is the acoustic wave device according to claim 1 and the second acoustic wave resonator is the acoustic wave device according to claim 1,
the first acoustic wave resonator and the second acoustic wave resonator share the piezoelectric layer, and
when a dimension of the hollow portion in the lamination direction of the piezoelectric substrate is a height of the hollow portion, a maximum height of the hollow portion of the first acoustic wave resonator is H1M, a maximum height of the hollow portion of the second acoustic wave resonator is H2M, a maximum thickness of a portion of the first region of the piezoelectric layer in which the first acoustic wave resonator is formed is T1M, and a maximum thickness of a portion of the first region of the piezoelectric layer in which the second acoustic wave resonator is formed is T2M, the maximum thickness T1M differs from the maximum thickness T2M, and the maximum height H1M differs from the maximum height H2M.

11. The filter device according to claim 10,
wherein both T2M>T1M and H2M>H1M hold.

12. The filter device according to claim 10,
wherein both T2M>T1M and H1M>H2M hold.

13. The filter device according to claim 10,
wherein the filter device is a ladder filter including at least one series arm resonator and at least one parallel arm resonator, the at least one series arm resonator includes the first acoustic wave resonator, and the at least one parallel arm resonator includes the second acoustic wave resonator.

14. A method of manufacturing the acoustic wave device according to claim 1, the method comprising:
a hollow portion forming step of forming the hollow portion in the piezoelectric substrate;
a thickness adjusting step of adjusting a thickness of the piezoelectric layer after the hollow portion forming step; and
a step of providing the excitation electrode on the piezoelectric layer,
wherein an inner wall of the piezoelectric substrate that faces the hollow portion includes a bottom portion of portions that face each other in the lamination direction of the piezoelectric substrate, the bottom portion being close to the support substrate, thinning machining of the piezoelectric layer is performed in the thickness adjusting step, pressure toward the hollow portion is applied to the piezoelectric layer to place the piezoelectric layer into a deformed state in the thinning machining, a distance between a center of the bottom portion and the piezoelectric layer is smaller than a distance between an outer peripheral edge of the bottom portion of the inner wall of the piezoelectric substrate and the piezoelectric layer in the deformed state, and the piezoelectric layer is further deformed such that a distance between the piezoelectric layer and the bottom portion is greater than the distance in the deformed state by releasing the pressure applied to the piezoelectric layer after the piezoelectric layer is placed into the deformed state to meet t1M>t2.

15. The method of manufacturing the acoustic wave device according to claim 14, further comprising:
a step of forming the intermediate layer between the piezoelectric layer and the support substrate before the hollow portion forming step,
wherein the hollow portion is formed in the intermediate layer in the hollow portion forming step.

16. The acoustic wave device according to claim 2,
wherein a portion of the piezoelectric layer that overlaps the hollow portion in plan view has a convex portion that projects away from the support substrate.

17. The acoustic wave device according to claim 16,
wherein the piezoelectric layer has a first main surface and a second main surface that face away from each other, and of the first main surface and the second main surface, the second main surface is closer to the support substrate, and a curvature at a border between the first region and the third region is greater than curvature of any other portion in the first region and curvature of any other portion in the third region in a cross-sectional shape in the lamination direction of the first main surface of the piezoelectric layer.

18. The acoustic wave device according to claim 17,
wherein at least a part of the hollow portion is provided in the piezoelectric layer.

19. The acoustic wave device according to claim 18,
wherein the piezoelectric substrate includes an intermediate layer provided between the support substrate and the piezoelectric layer, and at least a part of the hollow portion is provided in the intermediate layer.

20. The acoustic wave device according to claim 19,
wherein at least a part of the hollow portion is provided in the support substrate.
